(19) United States
(12) Patent Application Publication
(10) Pub. No.: US 2006/0170440 A1
(43) Pub. Date: Aug. 3, 2006

(54) Vertical probe card, probes for vertical probe card and method of making the same

(75) Inventor: Hendra Sudin, Hsinchu Hsiang (TW)

Correspondence Address: BACON & THOMAS, PLLC, 625 SLATERS LANE, FOURTH FLOOR, ALEXANDRIA, VA, 22314, US

(73) Assignee: MJC PROBE INCORPORATION, HSINCHU SHIEN (TW)

(21) Appl. No.: 11/325,376

(22) Filed: Jan. 5, 2006

(30) Foreign Application Priority Data
Feb. 2, 2005 (TW) 94103275

(51) Int. Cl. G01R 31/02

(52) U.S. Cl. 324/757

(57) ABSTRACT

A vertical probe card includes a circuit board and a probe set having a base and a plurality of probes provided at the base and electrically connected to the circuit board. Each probe has a foot, a tip and a middle body portion connected between the foot and the tip. The middle body portion has a coefficient of elasticity smaller than that of the base or the foot so that the middle body portion is forced to deform relative to the base when the tip touched a device under test.

### BACKGROUND OF THE INVENTION

1. Field of the Invention

The present invention relates to probe cards for probing on integrated circuits and more particularly, to a vertical probe card. The invention relates also to the fabrication of probes for vertical probe cards.

2. Description of the Related Art

A probe card for probing on integrated circuits comprises a plurality of vertical probes. A probe card uses the probes to electrically connect the bumps (pads) of the IC devices to a tester for transmitting test signal. The conventional probes of a probe card have a curved shape, and are made from metal wires through a mechanical machining process. When the probes of a probe card touched the pads (bumps) of the device under test, the curved structure of each probe absorbs the pressure, and therefore the probes are maintained positively contacted on the bumps (pads) of device under test.

However, because the aforesaid curved structure is produced through mechanical machining processes, for example, forging or stamping, the probes of same production show a great variation in size. Therefore, each probe of same production has a different structural strength, and the contact pressure cannot be evenly distributed through the probes when the probes touched the pads (bumps) of the device under test. Further, the conventional probes must be one by one manually placed to a guide plate assembly by skilled operator. This installation procedure is complicated, thus resulting in a high manufacturing cost. When testing a device sample having a high number of bumps (pads) or a different arrangement of bumps (pads), it will be difficult to accurately aim the probes at the bumps (pads) due to poor alignment between probes accumulated by manual hand placement process. Therefore, conventional probe cards are not practical for high frequency or high pin counts probing on modem integrated circuit (IC) chips or the like.

### SUMMARY OF THE INVENTION

The present invention has been accomplished under the circumstances in view. It is the main object of the present invention to provide a vertical probe card, which uses probes that have an elastic structure and the coefficient of elasticity and direction of angular deformation upon probing of each probe can be adjusted during fabrication which subject to different test requirements.

It is another object of the present invention to provide a vertical probe fabrication method, which allows control of the direction of angular deformation of the probe upon probing during fabrication and, which allows batch production to reduce the manufacturing cost.

To achieve these objects of the present invention, the vertical probe card comprises a circuit board and a probe set. The circuit board could be either made of materials such as ceramic based, organic based, silicon based, flexible substrate and their combinations or assembled constructions thereof. The probe set comprises a base and a plurality of probes provided at the base and electrically connected to the circuit board. Each probe comprises a foot, a tip, and a middle body portion connected between the foot and the tip. The middle body portion has a coefficient of elasticity smaller than that of the base so that the middle body portion is forced to deform relative to the base when the tip touched a bump (pad) of device under test. During fabrication, the locations, coefficient of elasticity and direction of deformation upon probing of the probes can be adjusted subject to different probing requirements.

### BRIEF DESCRIPTION OF THE DRAWINGS

FIG. 1 is a perspective view of a vertical probe card constructed according to a first embodiment of the present invention.

FIG. 2 is a front view of a probe constructed according to the first embodiment of the present invention.

FIG. 3 is a sectional view taken in an enlarged scale along line 3-3 of FIG. 2.

FIG. 4 corresponds to FIG. 2, showing the tip of the probe contacted on the bump or pad of device under test, the middle body portion of the probe deformed.

FIG. 5 is a schematic drawing showing the fabrication of the first embodiment of the present invention where a sacrificial layer is formed on a plane.

FIG. 6 corresponds to FIG. 5, showing a structural layer covered on the plane and the sacrificial layer.

FIG. 7 corresponds to FIG. 6, showing a composite layer formed on the plane.

FIG. 8 corresponds to FIG. 7, showing a sacrificial layer formed on the top side of the composite layer.

FIG. 9 corresponds to FIG. 8, showing a structural layer covered on the top side of the composite layer and the sacrificial layer.

FIG. 10 corresponds to FIG. 9, showing a second composite layer formed at the top side of the first composite layer.

FIG. 11 corresponds to FIG. 10, showing multiple composite layers produced and laminated one upon another.

FIG. 12 corresponds to FIG. 11, showing a predetermined number of composite layers produced and laminated one upon another.

FIG. 13 corresponds to FIG. 12, showing the status of the structure after removal of the sacrificial layers.

FIG. 14 shows the structure of a probe for probe card according to a second embodiment of the present invention.

FIG. 15 shows the structure of a probe for probe card according to a third embodiment of the present invention.

FIG. 16 shows the structure of a probe for probe card according to a fourth embodiment of the present invention.

FIG. 17 shows the structure of a probe for probe card according to a fifth embodiment of the present invention.

FIG. 18 shows the structure of a probe for probe card according to a sixth embodiment of the present invention.

FIG. 19 shows the structure of a probe for probe card according to a seventh embodiment of the present invention.

FIG. 20 shows the structure of a probe for probe card according to an eighth embodiment of the present invention.

### DETAILED DESCRIPTION OF THE INVENTION

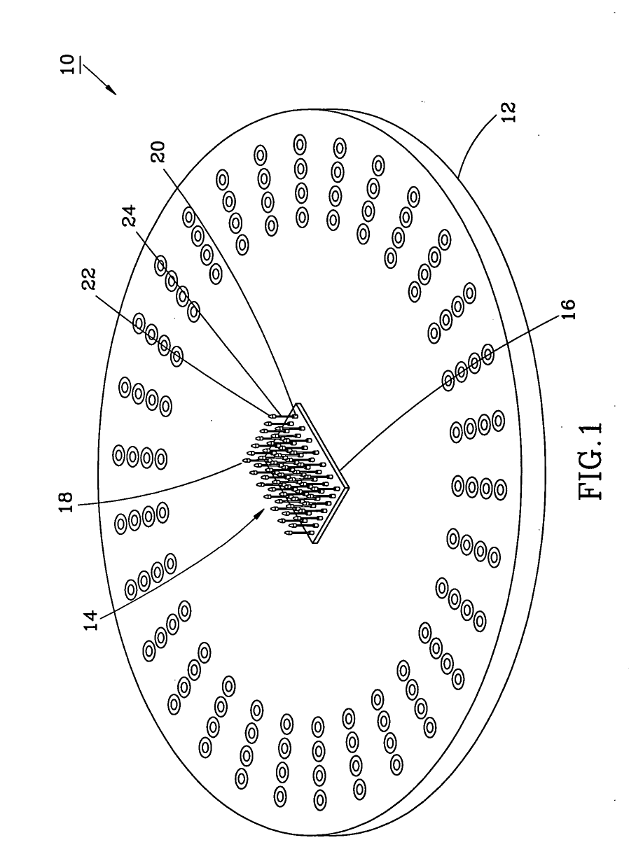

Referring to FIG. 1, a vertical probe card 10 in accordance with the first embodiment of the present invention is shown comprising a circuit board 12 and a probe set 14. The probe set 14 comprises a plate-like base 16 and an array of probes 18 perpendicularly arranged at the plate-like base 16.

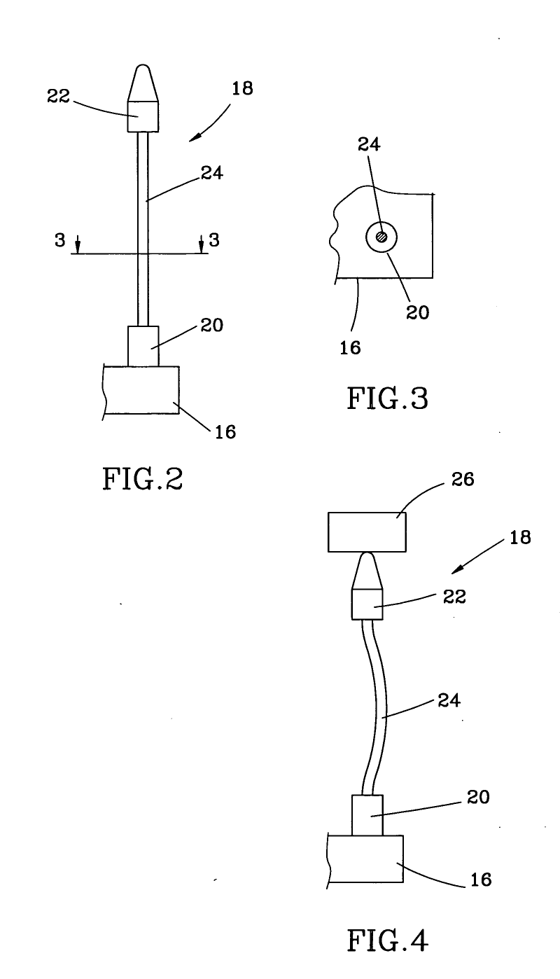

Referring to FIGS. 2-4 and FIG. 1 again, the probes 18 are respectively made from electrically conductive materials, such as nickel, palladium, magnesium, copper, beryllium, cobalt, rhodium or their alloys, each comprising a post-like foot 20, a tip 22, and a middle body portion 24 connected between the post-like foot 20 and the tip 22. The post-like foot 20 can be made having a circular, rectangular, or polygonal cross section. The post-like foot 20 is formed integral with the top surface of the plate-like base 16. The tip 22 has a conical top end, which has a diameter gradually reducing from the bottom side (the side connected to the middle body portion 24) toward the top side (the side remote from the middle body portion 24). The middle body portion 24 can be made having the shape of a round rod or flat plate. The area of the cross section of the middle body portion 24 is smaller than the area of the cross section of the post-like foot 20 and the area of the cross section of the bottom side of the tip 22. The height of the middle body portion 24 is greater than the height of the post-like foot 20. The middle body portion 24 is coaxially formed integral with the top surface of the post-like foot 20. The tip 22 is formed integral with the top end of the middle body portion 24. The conical top end of the tip 22 is adapted for touching at the pad (bumps) of device 26 under test.

Referring to FIG. 4 again, the area of the cross section of the middle body portion 24 is smaller than the area of the cross section of the post-like foot 20 and the height of the middle body portion 24 is greater than the height of the post-like foot 20, the coefficient of elasticity of the middle body portion 24 is smaller than the coefficient of elasticity of the post-like foot 20 subject to buckling theory. When contacting the tip 22 of one probe 18 on the device 26 under test, the middle body portion 24 and post-like foot 20 of the probe 18 receive a pressure from the tip 22. Upon such a pressure, the middle body portion 24 is forced to deform angularly relative to the post-like foot 20. Therefore, each probe 18 is elastic. When pressed on an uneven surface of the device 26 under test, the tip 22 of the probe 18 can still be maintained in close contact with the surface of the device 26 under test due to the effect of the elastic deformation property. If it is necessary to adjust the contact force between the device 26 under test and the probe 18, the adjustment can be done by changing the material of the middle body portion 24 to modify the coefficient of elasticity of the probe 18.

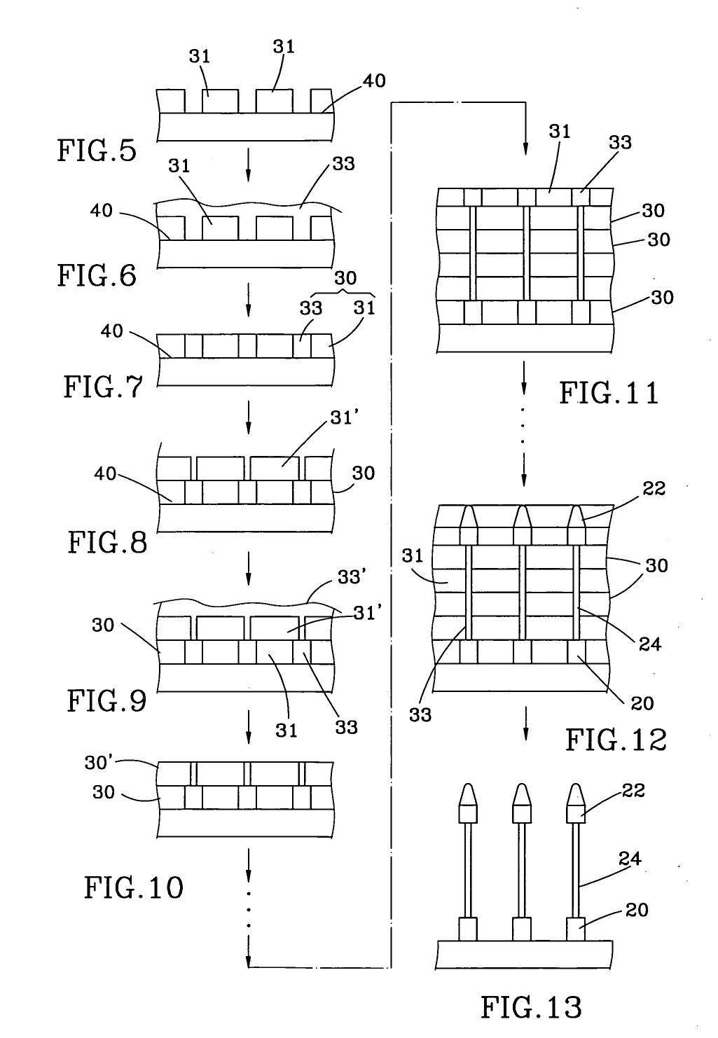

FIGS. 5-13 show the manufacturing processes of making probes 18 for a vertical probe card 10 according to the first embodiment of the present invention. Each probe 18 is comprised of multiple composite layers 30 that are laminated one upon another. The fabrication of each composite layer 30 includes the following three basic steps:

(a) forming on a plane 40 a sacrificial layer 31 having a predetermined pattern as shown in FIG. 5;

(b) laying out a structural layer 33, enabling the structural layer 33 to cover the top side of the plane 40 and the sacrificial layer 31 completely as shown in FIG. 6; and

(c) leveling the surface of the structural layer 33 to have the sacrificial layer 31 be exposed to the outside of the structural layer 33 and remained the same layer thickness with the structural layer 33 so as to form one composite layer 30 as shown in FIG. 7. At this time, the structural layer 33 is disposed at the plane 40 and presented in the shape of the array of the cross sections of the designed probes 18, and the locations of the probes 18 can be relatively adjusted subject to test requirements of the device 26 under test.

By means of the aforesaid three basic steps, a second composite layer 30′ is laminated on the top side of the first composite layer 30, keeping the two sacrificial layers 31, 31′ and the two structural layers 33, 33′ joined together. By means of repeating this procedure to laminate multiple composite layers 30 one upon another, a structure having portions corresponding to designed probes 18 each having a post-like foot 20, a tip 22, and a middle body portion 24 connected between the foot 20 and the tip 22 is thus formed as shown in FIGS. 11 and 12. Thereafter, an etching technology is employed to remove the sacrificial layer 31 of each composite layer 30, and therefore an array of probes 18 is produced, i.e., probes 18 are produced in batch.

Because the aforesaid probe fabrication method is an application of a lithography technology, the processing error reaches submicron grade, and probes produced at the same batch have a high uniformity in terms of size, shape, mechanical and electrical property. After having obtained the data of the location distribution of the bumps (pads) of the device 26 under test to be touched by the tips of the probes 18 and then designed the pattern of the structural layers 33, the desired probes 18 can then be easily produced. During fabrication, the locations of the probes are adjustable. A probe card made according to the present invention is practical for high frequency, high pin counts probing, fine pitch capability on modem IC chips or the like.

As indicated above, the invention allows adjustment of the coefficient of elasticity and locations of the probes of the probe card as well as the direction of deformation of the probes upon pressure subject to different probing requirements. Further, the invention allows batch production to simplify the fabrication and to reduce the manufacturing cost.

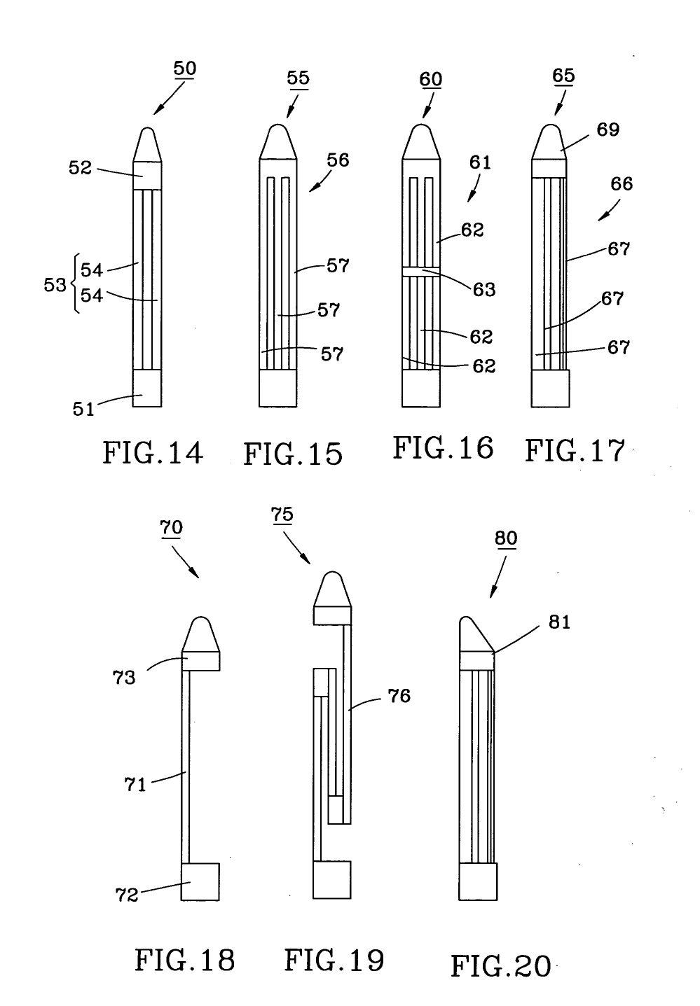

Further, the plate-like base of the probe set of the probe card can be formed integrally in a circuit board, keeping the probes joined to the circuit board. The circuit board could be either made of materials such as ceramic based, organic based, silicon based, flexible substrate and their combinations. The probes can be made having different shapes to provide different coefficient of elasticity. FIG. 14 shows a probe 50 for vertical probe card constructed according to the second embodiment of the present invention. As illustrated, the probe 50 comprises a foot 51, a tip 52, and a middle body portion 53 connected between the foot 51 and the tip 52. The middle body portion 53 comprises two elongated sidewalls 54 arranged in parallel and spaced from each other at a distance. The middle body portion 53 has a different coefficient of elasticity relative to the aforesaid first embodiment. FIG. 15 shows a probe 55 for vertical probe card constructed according to the third embodiment of the present invention. According to this embodiment, the middle body portion 56 of the probe 55 comprises three sidewalls 57 that provide a structural strength superior to the aforesaid second embodiment. FIG. 16 shows a probe 60 for vertical probe card constructed according to the fourth embodiment of the present invention. According to this embodiment, the middle body portion 61 of the probe 60 comprises three sidewalls 62 and a connection 63 joining the sidewalls 62. This embodiment has a structural strength superior to the aforesaid second and third embodiments.

By means of changing the structure of the probe can achieve control of the direction of deformation of the probe. FIG. 17 shows a probe 65 for vertical probe card constructed according to the fifth embodiment of the present invention. According to this embodiment, the middle body portion 66 of the probe 65 comprises three sidewalls 67 that have different cross sections. When the tip 69 of the probe 65 receives a pressure, the structure of the sidewalls 67 of the middle body portion 66 controls the direction of deformation of the probe 65. The sixth embodiment of the present invention as shown in FIG. 18 is an application of the same theory. As illustrated, the middle body portion 71 of the probe 70 according to the sixth embodiment of the present invention is formed of one single sidewall connected between the foot 72 and the tip 73 biased from the central axis passing through the tip 73 and the foot 72. The position of the middle body portion 71 controls the direction of deformation of the probe 70 upon a pressure. FIG. 19 shows a probe 75 for vertical probe card constructed according to the seventh embodiment of the present invention. According to this embodiment, the middle body portion 76 of the probe 75 has a folding structure. Subject to the design of the folding status of the middle body portion 76, the direction of deformation of the probe 75 is controlled. FIG. 20 shows a probe 80 for vertical probe card constructed according to the eighth embodiment of the present invention. According to this embodiment, the top edge of the tip 81 is biased from the central axis of the probe 80 at a distance. This design also achieves the objective of changing the direction of deformation of the probe 80.

What is claimed is:

1. A vertical probe card comprising:
a circuit board; and
a probe set comprising a base and a plurality of probes provided at said base and electrically connected to said circuit board, each said probe comprising a tip and a middle body portion connected between said base and said tip, said middle body portion having a coefficient of elasticity smaller than that of said base so that said middle body portion is forced to deform relative to said base when said tip touched a device under test.

2. The vertical probe card as claimed in claim 1, wherein said middle body portion has a cross section smaller than that of said base.

3. The vertical probe card as claimed in claim 1, wherein said middle body portion comprises two elongated sidewalls spaced from each other and arranged in parallel.

4. The vertical probe card as claimed in claim 1, wherein said middle body portion comprises three elongated sidewalls spaced from each other and arranged in parallel.

5. The vertical probe card as claimed in claim 4, wherein said middle body portion further comprises a connection joining said elongated sidewalls.

6. The vertical probe card as claimed in claim 1, wherein said middle body portion has a folding structure.

7. The vertical probe card as claimed in claim 1, wherein said tip has a topmost edge thereof biased from a central axis of the probe.

8. The vertical probe card as claimed in claim 1, wherein said middle body portion is a round rod.

9. The vertical probe card as claimed in claim 1, wherein said middle body portion is an elongated plate.

10. The vertical probe card as claimed in claim 1, wherein the circuit board is made from one or more materials selected from a group consisting of ceramic based material, organic based material, silicon based material, flexible substrate and the combinations thereof.

11. The vertical probe card as claimed in claim 1, wherein said probe set is made from one or more materials selected from a group consisting of nickel, palladium, magnesium, copper, beryllium, cobalt, rhodium and the alloys thereof.

12. A vertical probe comprising:
a foot;
a tip for touching a device under test; and
a middle body portion connected between said foot and said tip, said middle body portion having a coefficient of elasticity smaller than that of said base.

13. The vertical probe as claimed in claim 12, wherein said middle body portion has a cross section smaller than that of said foot.

14. The vertical probe as claimed in claim 12, wherein said middle body portion is comprised of two elongated sidewalls spaced from each other and arranged in parallel.

15. The vertical probe as claimed in claim 12, wherein said middle body portion is comprised of three elongated sidewalls spaced from each other and arranged in parallel.

16. The vertical probe as claimed in claim 15, wherein said middle body portion further comprises a connection joining said elongated sidewalls.

17. The vertical probe as claimed in claim 12, wherein said middle body portion has a folding structure.

18. The vertical probe as claimed in claim 12, wherein said tip has a topmost edge thereof biased from a central axis of the probe.

19. The vertical probe as claimed in claim 12, wherein said middle body portion is a round rod.

20. The vertical probe as claimed in claim 10, wherein said middle body portion is an elongated plate.

21. A vertical probe comprising:
a foot;
a tip for touching a device under test; and
a middle body portion connected between said foot and said tip, said middle body portion having a cross section smaller than that of said foot.

22. The vertical probe as claimed in claim 21, wherein said middle body portion is comprised of two elongated sidewalls spaced from each other and arranged in parallel.

23. The vertical probe as claimed in claim 21, wherein said middle body portion is comprised of three elongated sidewalls spaced from each other and arranged in parallel.

24. The vertical probe as claimed in claim 23, wherein said middle body portion further comprises a connection joining said elongated sidewalls.

25. The vertical probe as claimed in claim 21, wherein said middle body portion has a folding structure.

26. The vertical probe as claimed in claim 21, wherein said tip has a topmost edge thereof biased from a central axis of the probe.

27. The vertical probe as claimed in claim 21, wherein said middle body portion is a round rod.

28. The vertical probe as claimed in claim 21, wherein said middle body portion is an elongated plate.

29. A vertical probe fabrication method comprising the steps of:
(a) forming a sacrificial layer having a predetermined pattern;
(b) forming a structural layer on said sacrificial layer and having said structural layer covered over a whole top side of said sacrificial layer;
(c) leveling the surface of said structural layer to have said sacrificial layer be exposed to the outside of said structural layer and remained the same layer thickness with said structural layer so as to form one composite layer; and
(d) repeating the steps (a)-(c) to form multiple composite layers one laminated upon another and then removing the sacrificial layers of the multiple composite layers.

30. A vertical probe made according to the vertical probe fabrication method as claimed in claim 29.

31. The vertical probe as claimed in claim 30, comprising:
a foot;
a tip for touching a device under test; and
a middle body portion connected between said foot and said tip, said middle body portion having a coefficient of elasticity smaller than that of said foot so that said middle body portion is forced to deform relative to said foot when said tip touched the device under test.

32. The vertical probe as claimed in claim 31, wherein said middle body portion has a cross section smaller than that of said foot.
